(19) United States
(12) Patent Application Publication
(10) Pub. No.: US 2020/0090848 A1
(43) Pub. Date: Mar. 19, 2020

(54) MAGNETIC SUBSTRATE AND METHOD OF MANUFACTURING THE SAME, BONDING STRUCTURE BETWEEN MAGNETIC SUBSTRATE AND INSULATING MATERIAL, AND CHIP COMPONENT HAVING THE BONDING STRUCTURE

(71) Applicant: Samsung Electro-Mechanics Co., Ltd., Suwon-si (KR)

(72) Inventors: Sa Yong LEE, Suwon-si (KR); Yong Il KWON, Suwon-si (KR); Jin Ho HONG, Suwon-si (KR); Sung Han KIM, Suwon-si (KR); Keun Yong LEE, Suwon-si (KR)

(73) Assignee: Samsung Electro-Mechanics Co., Ltd., Suwon-si (KR)

(21) Appl. No.: 16/693,960

(22) Filed: Nov. 25, 2019

Related U.S. Application Data
(63) Continuation of application No. 14/502,578, filed on Sep. 30, 2014.

(30) Foreign Application Priority Data
Oct. 4, 2013 (KR) 10-2013-0118707

(51) Int. Cl. H01F 17/00

(52) U.S. Cl. CPC H01F 17/0013; Y10T 428/31612; H01L 2224/48091; H01L 2924/00014

(57) ABSTRACT

A chip component includes a magnetic substrate having ferrite layers, and an insulating layer disposed on the magnetic substrate and having an electrode disposed therein. An external electrode is connected to the electrode on the insulating layer. The magnetic substrate and the insulating layer have a chemical coupling structure formed on an interface therebetween. The chemical coupling structure includes Si—O—C or Si—O—N.

### CROSS REFERENCE TO RELATED APPLICATIONS

This application is a continuation of U.S. patent application Ser. No. 14/502,578 filed on Sep. 30, 2014, which claims the benefit under 35 USC 119(a) of Korean Patent Application No. 10-2013-0118707 filed on Oct. 4, 2013, in the Korean Intellectual Property Office, the entire disclosures of which are incorporated herein by reference for all purposes.

### TECHNICAL FIELD

The present invention relates to a magnetic substrate and a method of manufacturing the same, a bonding structure between the magnetic substrate and an insulating material, and a chip component having the bonding structure, and more specifically, to a magnetic substrate capable of improving close adhesion to an insulating material such as a polymer insulating layer and a method of manufacturing the same, a bonding structure between the magnetic substrate and an insulating material, and a chip component having the bonding structure.

### BACKGROUND

Recently, in accordance with a trend toward miniaturization, thinness, improvement in specifications, and multi-functionalization of electronic apparatuses, chip components used in electronic apparatuses have also been developed so as to satisfy the above-mentioned trend. Among these chip components, a passive device such as a common mode filter (CMF), a power inductor, or the like, is manufactured based on a predetermined magnetic substrate. A typical example of this magnetic substrate includes a magnetic substrate made of a ferrite material.

In order to form electrode patterns on the magnetic substrate, a seed layer should be formed on the magnetic substrate using a thin film forming process such as a metal sputtering process. However, a surface roughness of the ferrite magnetic substrate is significantly larger than a surface roughness required for effectively forming the seed layer. Therefore, in order to remove a difference between the surface roughnesses as described above, a predetermined insulating layer is formed on the magnetic substrate, and the electrode patterns are formed on the insulating layer. However, in bonding structures made of heterogeneous materials as described above, problems capable of decreasing reliability of the chip component occur, such as a crack, delamination, or the like, on a bonding interface because of low adhesion between the magnetic substrate and the insulating layer occur.

### RELATED ART DOCUMENT

Japanese Patent Laid-Open Publication No. 2013-0035474

### SUMMARY

The present disclosure provides a magnetic substrate capable of being used in a chip component, such as a thin film type or multilayer type passive device, and improving reliability of the chip component by improving adhesion to an insulating material having a roughness different from that of the magnetic substrate, and a method of manufacturing the same.

The present disclosure further provides a bonding structure between a magnetic substrate and an insulating material capable of preventing a phenomenon such as a crack, delamination, or the like, between the magnetic substrate and the insulating material, and a chip component having the bonding structure.

The present disclosure provide a bonding structure between a magnetic substrate and an insulating material capable of adhering a ferrite substrate and an insulating layer stacked on the ferrite substrate to each other at high adhesion, and a chip component having the bonding structure.

According to an exemplary embodiment of the present disclosure, there is provided a chip component including: a magnetic substrate having ferrite layers and an insulating layer disposed on the magnetic substrate and having an electrode disposed therein. An external electrode is connected to the electrode on the insulating layer. The magnetic substrate and the insulating layer have a chemical coupling structure formed on an interface therebetween, the chemical coupling structure includes Si—O—C or Si—O—N.

The magnetic substrate may be closely adhered to the insulating layer by chemical coupling using silanol groups (Si—OH) to form, together with the insulating layer, a bonding structure.

The magnetic substrate may include: a core layer having at least one first ferrite layer and a second ferrite layer having a content of glass higher than that of the core layer disposed between the core layer and the insulating layer.

The magnetic substrate may include: a core layer disposed at a central portion of the magnetic substrate, and an outer layer disposed at an outer side portion of the magnetic substrate relative to the core layer. The outer layer contains 1.0 to 5.0 wt % of glass components.

The magnetic substrate may be a stack body of a plurality of ferrite layers. An outer ferrite layer of the stack body adhered to the insulating layer may have a content of glass components higher than those of other ferrite layers.

The magnetic substrate may be a stack body of a plurality of ferrite layers, and an outer ferrite layer of the stack body closely adhered to the insulating layer may contain a glass component formed by firing or sintering at least any one selected from the group consisting of Bi₂O₃, ZnO, B₂O₃, and Al₂O₃; and SiO₂.

An outer ferrite layer closely adhered to the insulating layer among the ferrite layers may contain an oxide of at least any one selected from the group consisting of nickel (Ni), zinc (Zn), and copper (Cu); an oxide of iron (Fe); and a glass component. Layers other than the outer ferrite layer may contain an oxide of at least any one selected from the group consisting of nickel (Ni), zinc (Zn), and copper (Cu); and an oxide of iron (Fe).

The insulating layer may comprise a polymer insulating layer. The insulating layer may comprise a negative photosensitive material, wherein the negative photosensitive material includes at least one selected from the group consisting of a triphenol, a hydroxystyrene, and an epoxy compound.

The insulating layer may include at least any one selected from the group consisting of a naphthalene-based epoxy resin, a bisphenol A epoxy resin, a phenol novolac epoxy resin, a cresol novolac epoxy resin, a rubber-modified epoxy resin, a phosphoric epoxy resin, and a composite of these resins.

The insulating layer may include at least any one selected from the group consisting of a soluble thermosetting liquid crystal oligomer, a vinyl benzene-based monomer, and a polymer made of a multi-phenol.

The magnetic substrate may include a core layer having at least one ferrite layer and disposed at a central portion of the magnetic substrate. An outer layer is disposed at an outer side portion of the magnetic substrate relative to the core layer. The core layer has a thickness of 600 to 900 μm and the outer layer has a thickness of 150 to 350 μm.

According to another exemplary embodiment of the present disclosure, there is provided a chip component including: a magnetic substrate having ferrite layers and an electrode layer having an insulating layer covering the magnetic substrate and a coil electrode formed in the insulating layer. A magnetic composite material covers the electrode layer and has a hole exposing a portion of the coil electrode. An external electrode is enclosed by the magnetic composite material and is connected to the coil electrode through the hole. The magnetic substrate is closely adhered to the insulating layer by chemical coupling having a chemical structure of Si—O—C or Si—O—N.

An outer ferrite layer of the magnetic substrate disposed adjacent the insulating layer may have a content of glass component higher than that of a central layer of the magnetic substrate.

An outer ferrite layer of the magnetic substrate adhered to the insulating layer may contain 1.0 to 5.0 wt % of glass components.

An outer ferrite layer of the magnetic substrate adhered to the insulating may contain an oxide of at least any one selected from the group consisting of nickel (Ni), zinc (Zn), and copper (Cu); an oxide of iron (Fe); and the glass component. Ferrite layers other than the outer layer may contain an oxide of at least any one selected from the group consisting of nickel (Ni), zinc (Zn), and copper (Cu); and an oxide of iron (Fe).

The insulating layer may comprise a negative photosensitive material, wherein the negative photosensitive material includes at least one selected from the group consisting of a triphenol, a hydroxystyrene, and an epoxy compound.

The insulating layer may include at least any one selected from the group consisting of a naphthalene-based epoxy resin, a bisphenol A epoxy resin, a phenol novolac epoxy resin, a cresol novolac epoxy resin, a rubber-modified epoxy resin, a phosphoric epoxy resin, and a composite of these resins.

The insulating layer may include at least any one selected from the group consisting of a soluble thermosetting liquid crystal oligomer, a vinyl benzene-based monomer, and a polymer made of a multi-phenol.

The chip component may be a common mode noise filter for removing common mode noise generated from a high speed interface in a differential transmission scheme.

According to still another exemplary embodiment of the present disclosure, there is provided a magnetic substrate used in a thin film type or multilayer type passive device, including heterogeneous ferrite layers of which contents of glass components are different, comprising a structure in which a ferrite layer disposed at an outer side has a content of glass component that is relatively higher than the other ferrite layers.

The ferrite layer disposed at the outer side may have silanol groups (Si—OH) formed on a surface thereof.

The ferrite layer disposed at the outer side may have silanol groups (Si—OH) formed on a surface thereof, wherein the silanol groups are formed by firing or sintering a stack body of the ferrite layers to move a glass component in the ferrite layer disposed at the outer side to an interface of a firing cell of the stack body.

A content of the glass component may be 1.0 to 5.0 wt % based on the ferrite layer disposed at the outer side.

The glass component may be formed by firing or sintering at least any one selected from the group consisting of Bi₂O₃, ZnO, B₂O₃, and Al₂O₃; and SiO₂.

The ferrite layer disposed at the outer side may contain an oxide of at least any one selected from the group consisting of nickel (Ni), zinc (Zn), and copper (Cu); an oxide of iron (Fe); and the glass component. Ferrite layers other than the ferrite layer disposed at the outer side may contain an oxide of at least any one selected from the group consisting of nickel (Ni), zinc (Zn), and copper (Cu); and an oxide of iron (Fe).

At least one ferrite layer disposed the outer side may form an outer layer of the magnetic substrate, and ferrite layers other than the outer layer may form a core layer. The core layer has a thickness of 600 to 900 μm and the outer layer has a thickness of 150 to 350 μm.

The magnetic substrate may be used as a base substrate for manufacturing a common mode noise filter (CMF). The ferrite layer disposed at the outer side may be a layer adhered to an insulating layer of an electrode layer in which a coil electrode of the common mode noise filter is embedded. The glass component may form silanol groups on a surface of the ferrite layer disposed at the outer side.

According to yet still another exemplary embodiment of the present disclosure, there is provided a magnetic substrate manufactured by firing or sintering a multilayer structure in which ferrite sheets are stacked. The multilayer structure includes a core layer disposed at a central portion thereof and an outer layer stacked on the core layer and disposed at the outermost portion thereof The outer layer have silanol groups formed on a surface thereof.

The outer layer may be made of a ferrite sheet having a content of glass higher than the glass content of the ferrite sheets forming the core layer.

The silanol groups may be formed by adding a glass component to the ferrite sheet forming the outer layer.

The glass component may be formed by firing or sintering at least any one selected from the group consisting of Bi₂O₃, ZnO, B₂O₃, and Al₂O₃; and SiO₂.

The core layer may contain an oxide of at least any one selected from the group consisting of nickel (Ni), zinc (Zn), and copper (Cu); and an oxide of iron (Fe). The outer layer may contain an oxide of at least any one selected from the group consisting of nickel (Ni), zinc (Zn), and copper (Cu); an oxide of iron (Fe); and the glass component.

A content of the glass component may be 1.0 to 5.0 wt % based on the outer layer.

The glass component may be formed by firing or sintering at least any one selected from the group consisting of Bi₂O₃, ZnO, B₂O₃, and Al₂O₃; and SiO₂.

The core layer may have a thickness of 600 to 900 μm, and the outer layer may have a thickness of 150 to 350 μm.

According to yet still another exemplary embodiment of the present disclosure, there is provided a method of manufacturing a magnetic substrate, including preparing a first ferrite sheet and preparing a second ferrite sheet of which a content of glass component is higher than that of glass component of the first ferrite sheet. A sheet stack body is manufactured by stacking the second ferrite sheet on the first ferrite sheet, and firing or sintering the sheet stack body.

The preparing of the second ferrite sheet may include preparing a mixture of powders containing at least any one selected from the group consisting of Bi₂O₃, ZnO, B₂O₃, and Al₂O₃; and powders containing SiO₂. A slurry is prepared by mixing a binder and a solvent with the mixture, and forming the slurry into a sheet.

The preparing of the first ferrite sheet may include casting a ferrite raw material including powders containing an oxide of at least any one selected from the group consisting of nickel (Ni), zinc (Zn), and copper (Cu); and powders containing an oxide of iron (Fe). The preparation of the second ferrite sheet may include casting a ferrite raw material including powders containing an oxide of at least any one selected from the group consisting of nickel (Ni), zinc (Zn), and copper (Cu); powders containing an oxide of iron (Fe); and powders containing the glass component.

The manufacturing of the sheet stack body may include stacking a plurality of first ferrite sheets to manufacture a core layer, and stacking the second ferrite sheet on at least one surface of the core layer to manufacture an outer layer.

According to yet still another exemplary embodiment of the present disclosure, there is provided a bonding structure between a magnetic substrate and an insulating material. The bonding structure includes the magnetic substrate having ferrite layers and the insulating material closely adhered to the magnetic substrate by a chemical coupling structure including Si—O—C or Si—O—N.

The magnetic substrate may be closely adhered to the insulating material by chemical coupling using silanol groups (Si—OH).

The magnetic substrate may include a core layer having at least one first ferrite layer, and a second ferrite layer disposed adjacent the insulating material and having a content of glass higher than that of the core layer.

The magnetic substrate may include a core layer disposed at a central portion of the magnetic substrate and an outer layer disposed at an outer side portion of the magnetic substrate so as to be closely adhered to the insulating material. The outer layer contains 1.0 to 5.0 wt % of glass components.

The magnetic substrate may be a stack body of a plurality of ferrite layers. A ferrite layer closely adhered to the insulating material may contain a glass component formed by firing or sintering at least any one selected from the group consisting of Bi₂O₃, ZnO, B₂O₃, and Al₂O₃; and SiO₂.

An outer ferrite layer closely adhered to the insulating layer may contain an oxide of at least any one selected from the group consisting of nickel (Ni), zinc (Zn), and copper (Cu); an oxide of iron (Fe); and a glass component. Layers other than the outer ferrite layer adhered to the insulating material may contain an oxide of at least any one selected from the group consisting of nickel (Ni), zinc (Zn), and copper (Cu); and an oxide of iron (Fe).

The insulating material may comprise a polymer insulating layer. The insulating material may be a negative photosensitive material, wherein the negative photosensitive material includes at least one selected from the group consisting of a triphenol, a hydroxystyrene, and an epoxy compound.

The insulating material may include at least any one selected from the group consisting of a naphthalene-based epoxy resin, a bisphenol A epoxy resin, a phenol novolac epoxy resin, a cresol novolac epoxy resin, a rubber-modified epoxy resin, a phosphoric epoxy resin, and a composite of these resins.

The insulating material may include at least any one selected from the group consisting of a soluble thermosetting liquid crystal oligomer, a vinyl benzene-based monomer, and a polymer made of a multi-phenol.

The magnetic substrate may include a core layer having at least one ferrite layer. The core layer is disposed at a relatively central portion of the magnetic substrate. An outer layer is disposed at an outer side portion of the magnetic substrate relative to the core layer. The core layer has a thickness of 600 to 900 μm and the outer layer has a thickness of 150 to 350 μm.

The magnetic substrate may be a base substrate of a common mode noise filter, and the insulating material may be an insulating layer having a surface roughness smaller than that of the magnetic substrate in order to form a coil electrode on the base substrate.

According to yet another embodiment of the present disclosure, a chip component comprises a magnetic substrate comprising an outer ferrite layer and an inner ferrite layer. The outer ferrite layer has a greater glass content than the inner ferrite layer. An insulating layer is disposed on the outer ferrite layer and has a coil electrode disposed therein. The silicon in the outer ferrite layer is chemically bonded to carbon or nitrogen in the insulating layer via Si—O—C or Si—O—N bonds. The silicon may be bonded to carbon or nitrogen via Si—OH groups.

The chip component may further comprise an external electrode connected to the coil electrode.

A plurality of coil electrodes may be disposed in the insulating layer. The chip component may further comprise a plurality of external electrodes, wherein the plurality of external electrodes is connected to a corresponding coil electrode.

### BRIEF DESCRIPTION OF THE DRAWINGS

FIG. 1 is a view showing a chip component according to an exemplary embodiment of the present disclosure.

FIG. 2 is a view showing a magnetic substrate shown in FIG. 1.

FIG. 3 is an enlarged view of region A shown in FIG. 1.

FIG. 4 is a view showing resin components that may be used for a polymer insulating layer according to the exemplary embodiment of the present disclosure.

FIG. 5 is a flow chart showing a method of manufacturing a magnetic substrate according to the exemplary embodiment of the present disclosure.

FIGS. 6A to 6C are views for describing a process of manufacturing a magnetic substrate according to the exemplary embodiment of the present disclosure.

FIG. 7 is a view of a chip component according to an embodiment of the present disclosure.

### DETAILED DESCRIPTION

Various advantages and features of the present disclosure and methods accomplishing thereof will become apparent from the following description of exemplary embodiments with reference to the accompanying drawings. However, the present disclosure may be modified in many different forms and it should not be limited to the exemplary embodiments set forth herein. Rather, these exemplary embodiments may be provided so that this disclosure will be thorough and complete, and will fully convey the scope of the disclosure to those skilled in the art. Like reference numerals throughout the specification denote like elements.

Terms used in the present specification are for explaining the exemplary embodiments rather than limiting the present disclosure. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Further, the exemplary embodiments described in the specification will be described with reference to cross-sectional views and/or plan views that are ideal exemplification figures. In the drawings, the thickness of layers and regions is exaggerated for efficient description of technical contents. Therefore, the exemplary embodiments of the present disclosure are not limited to specific forms but may include the change in forms generated according to the manufacturing processes. For example, a region vertically shown may be rounded or may have a curvature.

Hereinafter, a magnetic substrate and a method of manufacturing the same, a bonding structure between the magnetic substrate and an insulating material, and a chip component having the bonding structure according to an exemplary embodiment of the present disclosure will be described in detail with reference to the accompanying drawings.

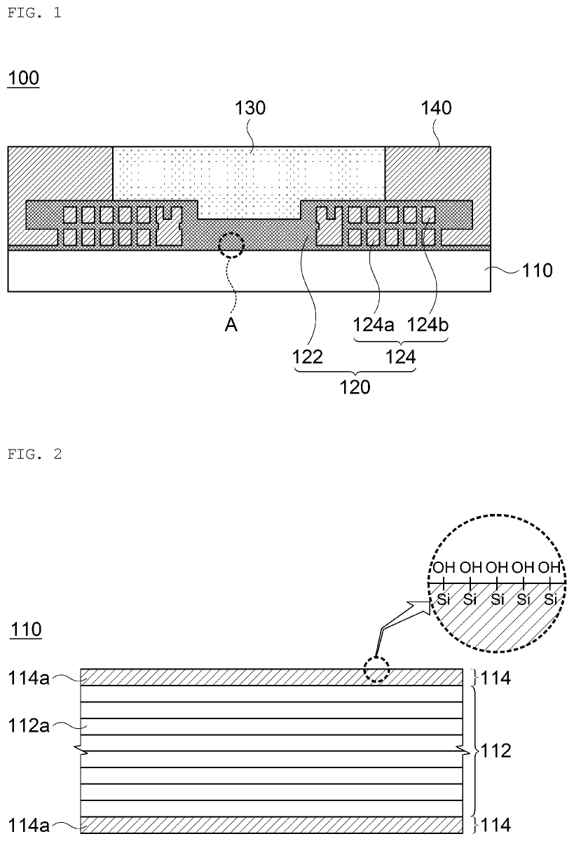

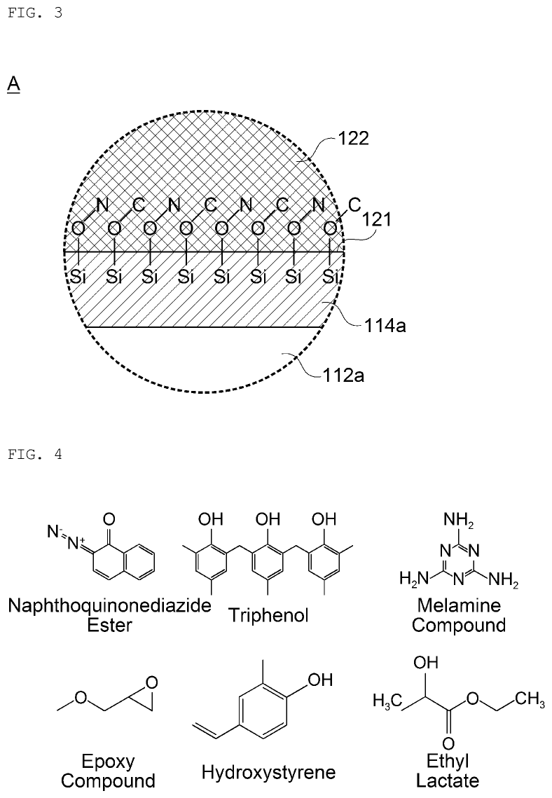

FIG. 1 is a view showing a chip component according to an exemplary embodiment of the present disclosure. FIG. 2 is a view showing a magnetic substrate shown in FIG. 1. FIG. 3 is an enlarged view of region A shown in FIG. 1. In addition, FIG. 4 is a view showing resin components that may be used for a polymer insulating layer according to the exemplary embodiment of the present disclosure.

Referring to FIGS. 1 to 4, the chip component 100 according to the exemplary embodiment of the present disclosure may be a passive device such as a common mode noise filter (CMF), a power inductor, or the like, and may be a multilayer or thin film passive device.

In the case in which the chip component 100 is the common mode noise filter, it may remove common mode noise generated from a high speed interface in a differential transmission scheme. In the case in which the chip component 100 is the power inductor, the chip component 100 may be an inductor used in a power supply circuit, such as a direct current (DC) to DC converter in a portable electronic apparatus, that is, a multilayer type power inductor.

As an example, the chip component 100, which is the common mode noise filter, may be configured to include a magnetic substrate 110, an electrode layer 120, a magnetic composite material 130, and an external electrode 140.

The magnetic substrate 110 may be used as a base substrate for manufacturing the electrode layer 120 and the external electrode 140. It may be preferable that the magnetic substrate 110 is made of a material having high electrical resistance and low magnetic loss in order to make a flow of magnetic flux generated in the electrode layer 120 at the time of applying a current to the chip component 100. As an example, it may be preferable that the magnetic substrate 110 is made of Ni—Zn, Mn—Zn based, Ni—Zn based, Ni—Zn—Mg based, Mn—Mg—Zn based ferrite, or a mixture thereof. Alternatively, the magnetic substrate 110 may be manufactured by adding at least any one selected from the group consisting of aluminum (Al), chromium (Cr), manganese (Mn), cobalt (Co), copper (Cu), zinc (Zn), niobium (Nb), molybdenum (Mo), indium (In), and tin (Sn) to the ferrite material as described above.

The magnetic substrate 110 may have a multilayer structure. The multilayer structure may be formed by firing or sintering a sheet stack body in which a plurality of ferrite sheets are stacked. The multilayer structure may have a core layer 112 and an outer layer 114 disposed at an outer side of the core layer 112. The core layer 112 may have at least one first ferrite layer 112a. As an example, the core layer 112 may have a stack structure in which a plurality of first ferrite layers 112a are stacked. The outer layer 114 may have at least one second ferrite layer 114a containing a glass component having a content higher than that of glass component of the first ferrite layer 112a. As an example, the second ferrite layer 114a may be stacked on one surface of the core layer 112 to form the outermost layer of the magnetic sheet stack body.

Main materials of the first and second ferrite layers 112a and 114a may be the same as or similar to each other, and contents of glass of the first and second ferrite layers 112a and 114a may be different from each other. As an example, the first ferrite layer 112a may be made of a ferrite material containing at least any one selected from the group consisting of nickel (Ni), zinc (Zn), and copper (Cu); and iron (Fe), and the second ferrite layer 114a may be made of a ferrite material containing at least any one selected from the group consisting of nickel (Ni), zinc (Zn), and copper (Cu); and iron (Fe); and the glass. In certain embodiments, the first ferrite layer 112a may be made of a ferrite material containing an oxide of at least any one selected from the group consisting of nickel (Ni), zinc (Zn), and copper (Cu); and an oxide of iron (Fe), and the second ferrite layer 114a may be made of a ferrite material containing an oxide of at least any one selected from the group consisting of nickel (Ni), zinc (Zn), and copper (Cu); an oxide of iron (Fe); and the glass. That is, the glass may not be contained in the first ferrite layer 112a or a smaller amount of glass may be contained in the first ferrite layer 112a than an amount of glass contained in the second ferrite layer 114a.

In addition, contents of iron (Fe) in the first and second ferrite layers 112a and 114a may be higher than those of other metals in the first and second ferrite layers 112a and 114a. As an example, contents of iron (Fe) in the first and second ferrite layers 112a and 114a may be approximately 60 wt % or more, and in certain embodiments, 65 wt % or more. An increased content of iron enables the magnetic substrate to sufficiently show its function. Contents of nickel (Ni) and zinc (Zn) other than the iron may be 25 wt % or less, and a content of copper (Cu) may be 10 wt % or less.

The glass component may form silanol groups (Si—OH) on a surface of the outer layer 114. As an example, the glass component may be formed by firing or sintering at least any one selected from the group consisting of Bi₂O₃, ZnO, B₂O₃, and Al₂O₃; and SiO₂. When heat treatment such as firing, sintering, or the like, is performed on the sheet stack body for manufacturing the first and second ferrite layers 112a and 114a, a glass component in a ferrite sheet that is to become the second ferrite layer 114a may move to an interface of a firing cell of the sheet stack body. A polishing process is performed on the surface of the firing shell as described above, such that the silanol groups formed on the interface may be exposed to the outside. Therefore, the silanol groups (Si—OH) may be formed on a surface of the second ferrite layer 114a. In this case, the silanol groups capable of effectively forming chemical coupling with a resin, silane, or the like, in the insulating layer 122 may be formed on a surface of the magnetic substrate 110 without generating a large loss of substrate magnetic permeability of the sheet stack body.

Meanwhile, a content of the glass component in the second ferrite layer 114a may be 5 wt % or less. As an example, in certain embodiments a content of glass component in the second ferrite layer 114a is controlled to be 1.0 wt % to 5.0 wt %. In the case in which the content of glass component in the second ferrite layer 114a is less than 1.0 wt %, the content of glass component is small, such that it may be difficult to sufficiently form the silanol groups for increasing close adhesion efficiency between the magnetic substrate 110 and the electrode layer 120. On the other hand, in the case in which the content of glass component in the second ferrite layer 114a exceeds 5 wt %, growth of a grain size of a grain cell of the ferrite sheet may be hindered and glass sintered materials having porosity may be non-uniformly grown on the surface. Therefore, the content of glass component in the second ferrite layer 114a may be controlled to be 1.0 to 5.0 wt % and in certain embodiments, may be controlled to be 1.5 to 3.5 wt %.

Here, although the case in which the magnetic substrate 110 is a magnetic substrate made of a ferrite material has been described by way of example in the above-mentioned exemplary embodiment, a material of the magnetic substrate 110 may be variously changed. For example, as another example of the present disclosure, a substrate having an oxide layer made of an inorganic oxide may be used as the magnetic substrate 110. As still another example of the present disclosure, a ceramic sheet, a varistor sheet, a substrate made of a liquid crystal polymer material, other various kinds of insulating sheets, or the like, may be used as the magnetic substrate 110.

Meanwhile, in the magnetic substrate 110 having the above-mentioned structure, the outer layer 114 may have a thickness thinner than that of the core layer 112. More specifically, since the outer layer 114 has the second ferrite layer 114a containing the glass component for forming the above-mentioned chemical coupling, it may have magnetic characteristics slightly lower than those of the core layer 112 having the first ferrite layer 112a. Therefore, the core layer 112 may have an increased thickness and the outer layer 114 has enough thickness to provide chemical coupling.

In a certain embodiment the core layer 112 may have a thickness of 70 to 85% or more based on the entire thickness of the magnetic substrate 110 and the outer layer 114 has a thickness of about 15 to 30% based on the entire thickness of the magnetic substrate 110. More specifically, the core layer 112 may be manufactured to have a thickness of approximately 600 to 900 μm by pressing and compressing first ferrite sheets 112a having a thickness of approximately 40 to 100 μm, and the outer layer 114 may be manufactured to have a thickness of approximately 150 to 350 μm by pressing and compressing second ferrite sheets 114a having a thickness of approximately 40 to 100 μm onto the core layer 112. Therefore, the entire thickness of the magnetic substrate 110 may be controlled to be approximately 750 to 1250 μm. The magnetic substrate 110 of which a detailed thickness is controlled as described above may maintain magnetic characteristics thereof while providing the chemical coupling using the silanol groups on a bonding surface between the magnetic substrate 110 and the electrode layer 120.

The electrode layer 120 may include an insulating layer 122 and coil electrodes 124 disposed in the insulating layer 122. The insulating layer 122 may be formed of a plurality of insulating sheets made of an insulating material such as a resin. The insulating layer 122 may be made of a polymer material, for example, a thermosetting resin such as an epoxy resin, a phenol resin, a urethane resin, a silicone resin, a polyimide resin, or the like, and a thermoplastic resin such as a polycarbonate resin, an acrylic resin, a polyacetal resin, a polypropylene resin, or the like.

In certain embodiments, the insulating layer 122 is a polymer insulating layer containing a polymer. More specifically, in the case in which the magnetic substrate 110 is the ferrite substrate, a surface roughness of the magnetic substrate 110 may be approximately 0.5 μm. In order to directly form the coil electrodes 124 on the magnetic substrate 110, a seed layer needs to be formed on the magnetic substrate 110 by performing a thin film forming process such as a metal sputtering process on the magnetic substrate 110. However, in order to secure sufficient adhesion between a thin film and a target on which the thin film is to be formed, a surface roughness of the target on which the thin film is to be formed needs to be approximately 0.05 μm or less.

Therefore, the polymer insulating layer may be used as the insulating layer 122 in order to remove a difference between the surface roughnesses as described above. In the case in which a ceramic insulating layer is used as the insulating layer 122, since adhesion between the ceramic insulating layer and a general thermosetting resin such as an epoxy resin is low, a separate process of bonding the ceramic insulating layer to the magnetic substrate 110 is added, such that manufacturing efficiency may be decreased. In addition, since the magnetic substrate 110 and the ceramic insulating layer are bonding structures made of significantly different materials, additional processes for increasing bonding efficiency at the time of bonding magnetic substrate 110 and the ceramic insulating layer to each other need to be performed. In this case, process conditions, or the like, may be very complicated.

A photosensitive insulating material capable of effectively forming chemical coupling with the silanol groups (Si—OH) of the magnetic substrate 110 may be used as the polymer material added to the insulating layer 122. In FIG. 4, exemplary photosensitive insulating materials are shown. These polymer materials, which are mainly negative photosensitive materials, may show a feature of forming a specific curing structure at the time of curing benzene rings including epoxy components and hydroxyl groups. The negative photosensitive materials showing this feature among the materials shown in FIG. 4 are a triphenol, a hydroxystyrene, an epoxy compound, and the like.

Meanwhile, hydroxyl groups on a ferrite surface may react with most the of epoxy groups and hydroxyl groups of the benzene rings. In this case, a chemical reaction may be performed with an amine or azide based curable agent or curing accelerator. A material capable of inducing the above-mentioned reaction may be at least any one selected from the group consisting of a naphthalene-based epoxy resin, a bisphenol A epoxy resin, a phenol novolac epoxy resin, a cresol novolac epoxy resin, a rubber-modified epoxy resin, a phosphoric epoxy resin, and a composite of these resins. Therefore, the above-mentioned resin material is used as a material of the polymer insulating layer, thereby making it possible to expect high chemical coupling efficiency. In addition to the above-mentioned materials, a soluble thermosetting liquid crystal oligomer, a vinyl benzene-based monomer such as styrene, hydroxyl styrene, and a polymer made of a multi-phenol may also be used as the material of the polymer insulating layer.

The coil electrodes 124 may be conductive patterns disposed on the insulating sheets. The coil electrodes 124 may be provided in a structure in which they are stacked over the insulating sheets so as to form a multilayer coil structure in the insulating layer 122. For example, the coil electrodes 124 may include first coils 124a and second coils 124b disposed on a plane different from a plane on which the first coils 124a are disposed. The first and second coils 124a and 124b may have a shape similar to each other. The first and second coils 124a and 124b may be spaced apart from each other with the insulating layer 122 disposed therebetween and be connected to each other by electrode vias (not shown) penetrating through the insulating layer 122.

In the coil electrode 124 having the structure as described above, when current flows to the first and second coils 124a and 124b in the same direction, magnetic fluxes are reinforced with each other to increase common mode impedance, thereby making it possible to suppress common mode noise. To the contrary, when current flows to the first and second coils 124a and 124b in different directions, magnetic fluxes are offset against with each other to decrease differential mode impedance, thereby making it possible to perform an operation of a common mode filter passing a desired transmission signal therethrough.

The magnetic composite material 130 may be provided on the electrode layer 120 so as to enclose the external electrode 140. In addition, the magnetic composite material 130 may have a hole exposing a portion of the coil electrode 124. The magnetic composite material 130 may be made of a composite material containing a magnetic material, a resin, a binder, and the like. For example, the magnetic composite material 130 may be made of Ni—Zn, Mn—Zn-based ferrite, Ni—Zn-based ferrite, Ni—Zn—Mg-based ferrite, Mn—Mg—Zn-based ferrite, or a mixture thereof. The magnetic composite material 130 made of the above-mentioned material may have characteristics such as high electrical resistance, low magnetic loss, and ease of an impedance design through a composition change.

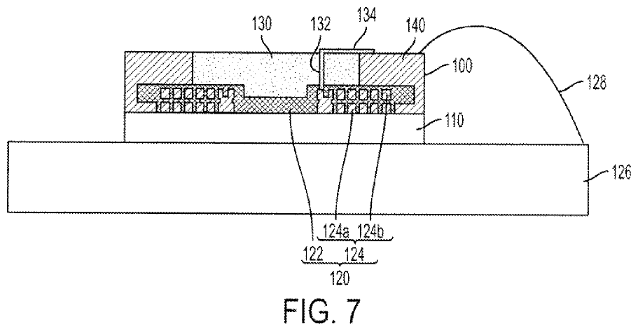

The external electrode 140 may electrically connect the chip component 100 to an external electronic apparatus 126 as shown in FIG. 7. The electrical connection may be through an electrical connector 128. The external electrode 140 may have a structure in which it covers an outer side region of the coil electrode 124 of the electrode layer 120. The external electrode 140 may be electrically connected to the coil electrode 124 exposed through a hole 132 in the magnetic composite material 130 via an electrical connector 134.

The chip component 100 may further include an electrostatic discharge protecting device (not shown). The electrostatic discharge protecting device, which absorbs and processes a surge current, a high voltage, a leakage current, and the like, at the time of generation of the surge current, the high voltage, the leakage current, and the like, may include an electrostatic discharge absorbing layer having a functional layer. The electrostatic discharge absorbing layer may be used as a functional layer absorbing or blocking electrostatic discharge (ESD). The electrostatic discharge absorbing layer, which allows a surge current to flow to a ground layer connected to the electrodes when the surge current is generated in the electrostatic discharge protecting device, a high voltage, a leakage current, and the like, may have an insulation feature before generation of the surge current and may generate a current path through which the surge current flows to the electrodes only at the time of generation of the surge current.

Meanwhile, the magnetic substrate 110 and the insulating layer 122 may be adhered to each other to form a single bonding structure. Here, the magnetic substrate 110 and the insulating layer 122 may have a structure in which they are adhered to each other by chemical coupling using silanol groups (Si—OH) in order to increase close adhesion therebetween. The chemical coupling may be provided by forming the silanol groups on the surface of the magnetic substrate 110 adhered to the insulating layer 122 and then adhering the magnetic substrate 110 and the insulating layer 122 to each other to allow the polymer materials in the insulating layer 122 and the silanol groups on the surface of the magnetic substrate 110 to form a coupling structure, such as Si—O—C or Si—O—N. Since the magnetic substrate 110 and the insulating layer 122 are adhered to each other by strong chemical coupling on a bonding interface 121 therebetween, the bonding structure as described above may prevent a phenomenon such as a crack, delamination, or the like.

As described above, the chip component 100 according to the exemplary embodiment of the present disclosure may be configured to include the magnetic substrate 110, which is a stack structure of the ferrite sheets, used as a base substrate; the electrode layer 120 stacked on the magnetic substrate 110; the magnetic composite material 130 covering the electrode layer 120 having the hole exposing a portion of the coil electrode 124 of the electrode layer 120; and the external electrode 140 connected to the coil electrode 124 through the hole, wherein the magnetic substrate 100 and the insulating layer 122 of the electrode layer 120 may have a structure in which they are closely adhered to each other by the chemical coupling having a chemical structure such as Si—O—C, Si—O—N, or the like. Therefore, the chip component according to the exemplary embodiment of the present disclosure has the bonding structure between the magnetic substrate and the insulating material in which the magnetic substrate and the insulating layer are strongly and closely adhered to each other, thereby making it possible to prevent disconnection, a short-circuit, a decrease in product reliability, and the like, due to a crack or delamination on an interface between the magnetic substrate and the insulating material.

The magnetic substrate 110 according to the exemplary embodiment of the present disclosure may be used in a thin film type or multilayer type passive device. The magnetic substrate 110 may include the first and second ferrite layers 112a and 114a of which the contents of glass components are different. The second ferrite layer 114a, in which a content of the glass component is higher than that of glass component of the first ferrite layer 112a, is disposed in the outer layer 114. The outer layer 114 may include the silanol groups (Si—OH) formed thereon in order to form the chemical coupling having the chemical structure such as Si—0-C, Si—O—N, or the like, with respect to the insulating layer 122 of the electrode layer 120, in which the coil electrodes 124 of the passive device are embedded. Therefore, the magnetic substrate according to the exemplary embodiment of the present disclosure may be used in the thin film or multilayer passive device The magnetic substrate 110 may include heterogeneous ferrite layers of which contents of glass components are different, and have a structure in which an outer ferrite layer, in which a content of glass component is higher than the other ferrite layers, and the silanol groups for chemical coupling with the insulating layer for forming the coil electrode of the passive device are formed on the surface of the outer layer, such that the magnetic substrate is closely adhered to the insulating layer at high close adhesion by the chemical coupling.

A method of manufacturing a magnetic substrate according to the exemplary embodiment of the present disclosure will be described in detail herein. However, a description that overlaps with that of the above-mentioned magnetic sheet stack body 110 may be omitted or simplified.

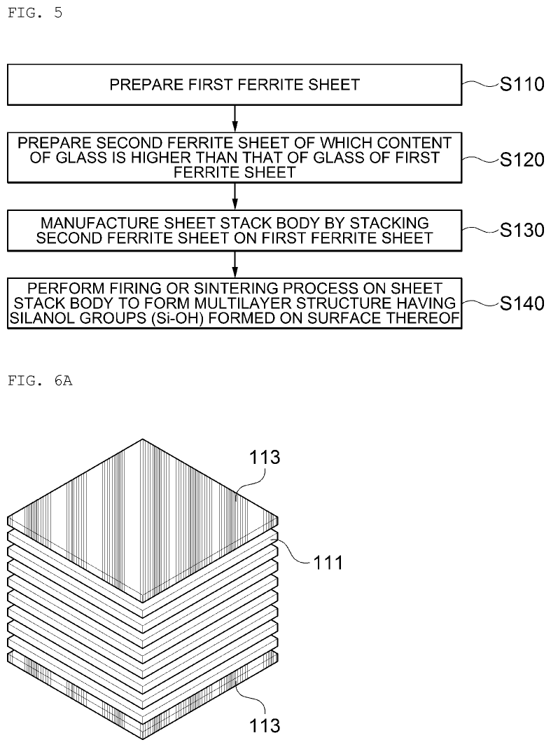

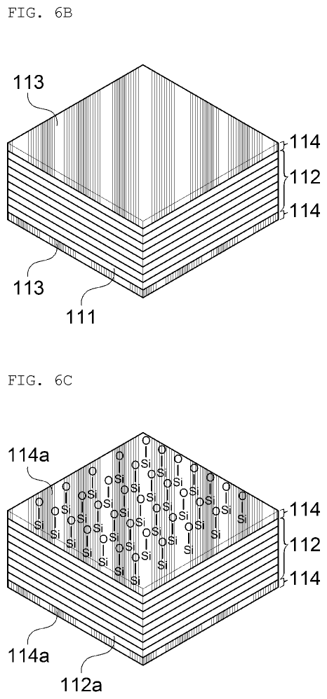

FIG. 5 is a flow chart showing a method of manufacturing a magnetic substrate according to an exemplary embodiment of the present disclosure. FIGS. 6A to 6C are views for describing a process of manufacturing a magnetic substrate according to the exemplary embodiment of the present disclosure.

Referring to FIGS. 5 and 6A, a first ferrite sheet 111 may be prepared (S110). The preparing of the first ferrite sheet 111 may include preparing a first slurry by mixing a ferrite material used as a main raw material with an organic binder and a solvent and manufacturing a first green sheet by casting the first slurry. The first slurry may be prepared by controlling contents of the respective components so that a content of Fe₂O₃ powders is 65 to 67 wt %, a content of NiO powders is 7 to 25 wt %, a content of ZnO powders is 6 to 27 wt %, and a content of CuO powders is 4 to 8 wt % and then mixing the respective components with each other. The first green sheet may be manufactured at a thickness of approximately 40 to 100 μm. It may be difficult in view of the process and technology to manufacture the first green sheet at a thickness less than 40 μm. On the other hand, when the first green sheet is manufactured at a thickness exceeding 100 μm, it may be difficult to precisely control a thickness at the time of manufacturing a stack body of the first ferrite sheets 111 and workability and a handling property may be significantly decreased. Through the above-described process, the first ferrite sheet 111 that contains either no glass component or a very small amount of glass component may be manufactured.

A second ferrite sheet 113 in which a content of the glass component is higher than that of glass component of the first ferrite sheet 111 may be prepared (S120). The preparing of the second ferrite sheet 113 may include preparing a second slurry by mixing a ferrite material used as a main raw material with an organic binder, a solvent, and a glass component and manufacturing a second green sheet by casting the second slurry.

The second slurry may be prepared by mixing Fe₂O₃ powders of 65 to 66 wt %, NiO powders of 7 to 25 wt %, ZnO powders of 6 to 22 wt %, and CuO powders of 4 to 7 wt % with each other. The glass component may be mixed with the second slurry at a content ratio of approximately 1.5 to 3.0 wt %. As the glass component, at least any one selected from the group consisting of Bi₂O₃, ZnO, B₂O₃, and Al₂O₃; and SiO₂ may be used. More specifically, Bi₂O₃ may be added in a content of approximately 60 wt % or more based on the glass component, ZnO and B₂O₃ may be added in a content of approximately 5 to 20 wt % based on the glass component, and Al₂O₃ and SiO₂ may be added in a content of less than 5 wt % based on the glass component.

The second green sheet is manufactured at a thickness of approximately 40 to 100 μm. It may be difficult in view of a process and a technology to manufacture the second green sheet at a thickness less than 40 μm. On the other hand, when the second green sheet is manufactured at a thickness exceeding 100 μm, it may be difficult to precisely control a thickness at the time of manufacturing a stack body of the second ferrite sheets 113 and workability and a handling property may be significantly decreased. Through the above-mentioned process, the second ferrite sheet 113 containing the glass component may be manufactured.

A sheet stack body may be manufactured by stacking the second ferrite sheet 113 on the first ferrite sheet 111 (S130). As an example, a plurality of first ferrite sheets 111 may be stacked and compressed to manufacture a core layer 112, which is a sheet stack body. The sheet stack body may have a thickness of approximately 600 to 900 μm. In addition, a plurality of second ferrite sheets 113 may be stacked and compressed on at least one surface of the core layer 112 to manufacture an outer layer 114 having a thickness of approximately 150 to 350 μm. Therefore, a sheet stack body having a thickness of approximately 1100 to 1200 μm, and including the core layer 112 and the outer layer 114 may be manufactured.

A firing or sintering process may be performed on the sheet stack body to form a multilayer structure having silanol groups (Si—OH) formed on a surface thereof (S140). In the performing of the firing or sintering process on the sheet stack body, compressing and heat treating processes may be performed on the sheet stack body. In this case, the glass in the outer layer 114 of the sheet stack body may move to an interface of a firing cell of the magnetic sheet stack body. A polishing process to expose the interface is performed on the firing cell, such that the multilayer structure having a large number of silanol groups (Si—OH) formed on the surface thereof may be formed. Therefore, the magnetic substrate 110 shown in FIG. 2 having the silanol groups (Si—OH) formed on the surface of the outer layer 114 and capable of being chemically coupled to the polymer insulating material may be manufactured.

As described above, the method of manufacturing a magnetic substrate according to the exemplary embodiment of the present disclosure may include preparing the first ferrite sheet 111, preparing the second ferrite sheet 113 of which a content of glass is higher than that of glass of the first ferrite sheet 111, stacking the second ferrite sheet 113 on the first ferrite sheet 111 to form the multilayer structure, and firing or sintering the multilayer structure. In this case, the second ferrite sheet 113 may form the outer layer 114 of the multilayer structure, and the silanol groups (Si—OH) may be formed on the surface of the outer layer 114 by the glass in the second ferrite sheet 113 in the firing or sintering. The multilayer structure as described above may increase close adhesion to the insulating layer 122 by the silanol groups at the time of being bonded to an external insulating material, for example, the insulating layer 122. Therefore, in the method of manufacturing a magnetic substrate according to an exemplary embodiment of the present disclosure, the magnetic substrate bonded to a heterogeneous material, for example, an insulating material at strongly adhered by chemical coupling to prevent disconnection, a short-circuit, a decrease in product reliability, and the like, due to a crack or delamination on a bonding interface may be manufactured.

The chip component according to an exemplary embodiment of the present disclosure includes the magnetic substrate, the electrode layer stacked on the magnetic substrate, the ferrite composite material covering the electrode layer and having the hole exposing a portion of the coil electrode of the electrode layer, and the external electrode connected to the coil electrode through the hole, wherein the magnetic substrate and the insulating layer of the electrode layer may have a structure in which they are closely adhered to each other by the chemical coupling having a chemical structure such as Si—O—C, Si—O—N, or the like. Therefore, the chip component according to the exemplary embodiment of the present disclosure has the bonding structure between the magnetic substrate and the insulating material in which the magnetic substrate and the insulating layer are closely adhered to each other at high close adhesion, thereby making it possible to prevent disconnection, a short-circuit, a decrease in product reliability, and the like, due to a crack or delamination on an interface between the magnetic substrate and the insulating material.

The magnetic substrate according to the exemplary embodiment of the present disclosure may be used in a thin film or multilayer passive devices. The magnetic substrate includes heterogeneous ferrite layers, in which glass component contents are different, and have a structure in which an outer ferrite layer has a content of glass component that is higher than the other ferrite layers and the silanol groups for chemical coupling with the insulating layer for forming the coil electrode of the passive device are formed on the surface of the outer layer, such that the magnetic substrate is closely adhered to the insulating layer at high close adhesion by the chemical coupling.

The method of manufacturing a magnetic substrate according to an exemplary embodiment of the present disclosure may include preparing the first ferrite sheet, preparing the second ferrite sheet, in which a glass content is higher than that of the glass content of the first ferrite sheet, stacking the second ferrite sheet on the first ferrite sheet to form the multilayer structure, and firing or sintering the multilayer structure. In this case, in the firing or sintering of the multilayer structure, the silanol groups (Si—OH) may be formed on the surface of the multilayer structure by the glass in the second ferrite sheet, and the multilayer structure may increase close adhesion to the insulating layer by the chemical coupling using the silanol groups at the time of being bonded to an external insulating material, for example, the polymer insulating layer. Therefore, in the method of manufacturing a magnetic substrate according to the exemplary embodiment of the present disclosure, the magnetic substrate is bonded to a heterogeneous material, for example, an insulating material at high close adhesion by the chemical coupling to prevent disconnection, a short-circuit, a decrease in product reliability, and the like, due to a crack or delamination on a bonding interface may be manufactured.

The present disclosure has been described in connection with what is presently considered to be practical exemplary embodiments. In addition, the above-mentioned description discloses only the exemplary embodiments of the present disclosure. Therefore, it is appreciated that modifications and alterations may be made by those skilled in the art without departing from the scope of the present disclosure disclosed in the present specification and an equivalent thereof. The exemplary embodiments described above have been provided to explain the best state in carrying out the present disclosure. Therefore, they may be carried out in other states known to the field to which the present disclosure pertains in using other disclosures such as the present disclosure and also be modified in various forms required in specific application fields and usages of the disclosure. Therefore, it is understood that the disclosure is not limited to the disclosed embodiments. It is understood that other embodiments are also included within the spirit and scope of the appended claims.

What is claimed is:

1. A chip component, comprising:
a magnetic substrate comprising ferrite layers;
an insulating layer, disposed on the magnetic substrate, having an electrode disposed therein, wherein the magnetic substrate and the insulating layer have a chemical coupling structure formed on an interface therebetween, the chemical coupling structure comprising Si—O—C or Si—O—N; and
an external electrode connected to the electrode on the insulating layer,
wherein one ferrite layer of the ferrite layers in contact with another ferrite layer of the ferrite layers each comprises a glass component, glass component concentrations of the one ferrite layer in contact with the another ferrite layer are different from each other, and the one ferrite layer or the another ferrite layer with a higher glass component concentration is in contact with the insulating layer.

2. The chip component according to claim 1, wherein each of the ferrite layers comprises a glass component.

3. The chip component according to claim 1, wherein the magnetic substrate is adhered to the insulating layer by chemical coupling using silanol groups (Si—OH) to form, together with the insulating layer, a bonding structure.

4. The chip component according to claim 1, wherein the magnetic substrate comprises:
a core layer having at least one first ferrite layer; and
a second ferrite layer disposed between the core layer and the insulating layer and having a glass content higher than that of the core layer.

5. The chip component according to claim 1, wherein the magnetic substrate comprises:
a core layer disposed at a central portion of the magnetic substrate; and
an outer layer disposed at an outer side portion of the magnetic substrate relative to the core layer, wherein the outer layer comprises 1.0 to 5.0 wt % of glass components.

6. The chip component according to claim 1, wherein the magnetic substrate is a stack body of a plurality of ferrite layers, and
an outer ferrite layer of the stack body adhered to the insulating layer has a content of glass components higher than those of other ferrite layers.

7. The chip component according to claim 1, wherein the magnetic substrate is a stack body of the plurality of ferrite layers, and
an outer ferrite layer of the stack body adhered to the insulating layer contains a glass component moved by firing or sintering at least any one selected from the group consisting of Bi₂O₃, ZnO, B₂O₃, and Al₂O₃; and SiO₂.

8. The chip component according to claim 1, wherein the insulating layer comprises a polymer insulating layer.

9. A chip component, comprising:
a magnetic substrate comprising ferrite layers;
an electrode layer having an insulating layer covering the magnetic substrate and a coil electrode formed in the insulating layer, wherein the magnetic substrate is adhered to the insulating layer by chemical coupling having a chemical structure of Si—O—C or Si—O—N;
a magnetic composite material, covering the electrode layer, comprising a hole exposing a portion of the coil electrode; and
an external electrode, enclosed by the magnetic composite material, connected to the coil electrode through the hole,
wherein one ferrite layer of the ferrite layers in contact with another ferrite layer of the ferrite layers each comprises a glass component, the glass component concentrations of the one ferrite layer in contact with the another ferrite layer are different from each other, and the one ferrite layer or the another ferrite layer with a higher glass component concentration is in contact with the insulating layer.

10. The chip component according to claim 9, wherein each of the ferrite layers comprises a glass component.

11. The chip component according to claim 9, wherein an outer ferrite layer of the magnetic substrate, adhered to the insulating layer, comprises 1.0 to 5.0 wt % of glass components.

12. The chip component according to claim 9, wherein the chip component is a common mode noise filter for removing common mode noise generated from a high speed interface in a differential transmission scheme.

13. A magnetic substrate manufactured by firing or sintering a multilayer structure in which ferrite sheets are stacked,
wherein the multilayer structure comprises a core layer disposed at a central portion thereof and an outer layer stacked on the core layer and disposed at an outermost portion thereof, and the outer layer has silanol groups formed on a surface thereof, and
wherein the outer layer in contact with the core layer each comprises a glass component, glass component concentrations of the outer layer in contact with the core layer are different from each other, and the outer layer has a higher glass component concentration and is in contact with an insulating layer.

14. The magnetic substrate according to claim 13, wherein each of the ferrite sheets comprises a glass component.

15. The magnetic substrate according to claim 13, wherein the silanol groups are formed by adding a glass component to the ferrite sheet forming the outer layer.

16. A bonding structure between a magnetic substrate and an insulating material,
wherein the magnetic substrate comprises ferrite layers, and the insulating material adheres to the magnetic substrate by a chemical coupling structure comprising Si—O—C or Si—O—N, and
wherein one ferrite layer of the ferrite layers in contact with another ferrite layer of the ferrite layers each comprises a glass component, glass component concentrations of the one ferrite layer in contact with the another ferrite layer are different from each other, and the one ferrite layer or the another ferrite layer with a higher glass component concentration is in contact with the insulating material.

17. The bonding structure according to claim 16, wherein each of the ferrite layers comprises a glass component.

18. The bonding structure according to claim 16, wherein the magnetic substrate is a base substrate of a common mode noise filter, and
the insulating material is an insulating layer having a surface roughness smaller than that of the magnetic substrate to form a coil electrode on the base substrate.
